(19) United States
(12) Patent Application Publication
(10) Pub. No.: US 2025/0006407 A1
(43) Pub. Date: Jan. 2, 2025

(54) WIRING HARNESS PRODUCTION METHOD, NOZZLE, AND WIRING HARNESS

(71) Applicant: Changchun Jetty Automotive Technology Co., Ltd., Changchun, Jilin (CN)

(72) Inventors: Chao WANG, Changchun, Jilin (CN); Yun MIAO, Changchun, Jilin (CN)

(73) Assignee: Changchun Jetty Automotive Technology Co., Ltd., Changchun, Jilin (CN)

(21) Appl. No.: 18/292,900

(22) PCT Filed: Jul. 15, 2022
(86) PCT No.: PCT/CN2022/105976

§ 371 Date: Jan. 27, 2024

(30) Foreign Application Priority Data
Jul. 30, 2021 (CN) 202110875947.7

(51) Int. Cl. H01B 13/012; H01B 7/00

(52) U.S. Cl. CPC H01B 13/01254; H01B 7/0045

(57) ABSTRACT

The present disclosure provides a wiring harness production method, a nozzle and a wiring harness. The wiring harness production method includes: Step S10: preparing a substrate; Step S20: spraying a conductive material onto the substrate to form a conductive loop; and Step S30: forming an insulating protective layer at the periphery of the conductive loop and on a surface thereof. The present disclosure solves the technical problems of complex production process and high processing cost of a wiring harness for electrically connecting electrical components.

### RELATED APPLICATION

The present disclosure claims priority of the Chinese invention patent with an application number of CN202110875947.7, an invention title of ‘wiring harness production method, nozzle and wiring harness’ and filed on Jul. 30, 2021.

### TECHNICAL FIELD

The present disclosure relates to the technical field of electronic components, and particularly to a wiring harness production method, a nozzle and a wiring harness.

### BACKGROUND

An electrical connection needs to be realized by wiring harness. The existing wiring harness is mainly composed of parts such as electrical wires, terminals, sheaths, positioning pieces and brackets, etc. The parts are numerous, the structure is complex, and the electrical wires in the wiring harness should be produced through the processes of conductor drawing, stranding, annealing, extrusion molding of insulation layer and so on, so the production process is complex, and the processing cost is high. Most of the existing wiring harness production methods use the mode of centralized mass production.

Some wiring harness products of small batches and various product types have high requirements for flexible production and cannot be mass-produced. Such wiring harnesses can only be produced by manual works and temporary tooling, so the processing cycle is long and the production cost is increased.

### SUMMARY

An objective of the present disclosure is to provide a wiring harness production method, a nozzle and a wiring harness, so as to alleviate the technical problems of complex production process and high processing cost of a wiring harness for electrically connecting electrical components.

The above objective of the present disclosure can be achieved by the following technical solutions.

The present disclosure provides a wiring harness production method, including: Step S10: preparing a substrate; Step S20: spraying a conductive paint onto the substrate to form a conductive loop; and Step S30: forming an insulating protective layer at the periphery of the conductive loop and on a surface thereof.

The present disclosure provides a nozzle, which is applied to the wiring harness production method aforementioned, and a discharge port of the nozzle is square.

The present disclosure provides a wiring harness, which is produced by the wiring harness production method aforementioned, the wiring harness including: a substrate, at least one conductive loop and at least one insulating protective layer, in which each conductive loop is located between the substrate and the outermost insulating protective layer, and the conductive loop and the insulating protective layer are alternately distributed.

The present disclosure has the following characteristics and advantages:

The wiring harness production method adopts spraying to form a conductive loop onto the substrate, in which the conductive loop may be connected to an external electrical component to realize the electrical connection function of the wiring harness; and performs an insulating protection by an insulating protective layer, thereby realizing the rapid formation of a wiring harness loop. The wiring harness production method has the following advantages:

(1) By adopting spraying to produce the wiring harness, the flexible production degree is high, the processing is fast and convenient, the efficiency is high, and the cost is far less than the existing small-batch wiring harness production mode.

(2) Multi-layer spraying can be adopted to prepare more conductive loops under the condition of a small area of the substrate, thereby meeting the demand for more electrical loops.

(3) By punching a hole and pouring a conductive material, it is possible to electrically connect the conductive loops of different layers, and realize the design scheme of a complex electrical loop, which is suitable for to more complex wiring harnesses.

(4) The cross-sectional area of the conductive loop can be adjusted by adjusting spraying parameters, which is suitable for the processing of the multi-wire diameter loop, and is convenient to control the conductivity of the conductive loop.

(5) The trajectory of the nozzle is controlled by a servo mechanism or a manipulator, which is convenient to process and realize the wiring harness with a complex spatial structure, and ensure stable spraying to keep a uniform size of the conductive loop.

(6) The material selection for the insulating protective layer is diverse, and an insulation protection can be realized by adopting a plurality of process modes to ensure the insulation protection effect.

(7) The substrate may be a constituent part of an electrical component, and can realize an integrated production of the components and the wiring harness, thereby achieving the rapid mounting and dismounting of the wiring harness.

(8) A profile modeling substrate may be adopted and spraying may be performed onto a non-planar substrate, thereby extending the application environment of the sprayed wiring harness.

(9) A flexible substrate may be adopted, so that the sprayed wiring harness can be suitable for various mounting situations. The produced wiring harness can be applied to the electrical components in complex mounting environments, and can also be used in environments with high vibration requirements to reduce the interference of vibration factors.

(10) When the wiring harness is damaged, the damaged substrate can be directly replaced without dismantling and replacing the whole wiring harness, which not only saves maintenance man-hours but also reduces the maintenance cost.

(11) A shielding structure is provided outside the wiring harness, so that a signal in the wiring harness can be shielded from electromagnetic interference at a position with strong electromagnetic interference, thereby ensuring the stability of the signal.

(12) Heat sinks are provided on the insulating protective layer to quickly dissipate heat generated by the current of the wiring harness into the air, which is beneficial to decreasing the temperature of the wiring harness and reducing the fusing risk of the conductive loop.

### BRIEF DESCRIPTION OF THE DRAWINGS

The following drawings are only for schematic illustration and explanation of the present disclosure, rather than limiting the scope thereof. In which:

FIG. 1 illustrates a schematic diagram of a wiring harness production method according to the present disclosure;

FIG. 2 illustrates a schematic working diagram of a wiring harness production method according to the present disclosure;

FIGS. 3 and 4 illustrate schematic structural diagrams of a wiring harness produced by a wiring harness production method according to the present disclosure;

FIGS. 5 and 6 illustrate schematic structural diagrams of a nozzle in a wiring harness production method according to the present disclosure;

FIG. 7 illustrates a top view of an embodiment of a wiring harness produced by a wiring harness production method according to the present disclosure;

FIG. 8 illustrates a side cross-sectional view of an embodiment of a wiring harness produced by a wiring harness production method according to the present disclosure;

FIG. 9 illustrates a top view of another embodiment of a wiring harness produced by a wiring harness production method according to the present disclosure; and

FIG. 10 illustrates a side cross-sectional view of another embodiment of a wiring harness produced by a wiring harness production method according to the present disclosure.

### DESCRIPTION OF EMBODIMENTS

In order to have a clearer understanding of the technical features, objectives and effects of the present disclosure, specific embodiments of the present disclosure will be described below with reference to the drawings. In the description of the present disclosure, unless otherwise specified, ‘a plurality of’ means two or more.

### Embodiment 1

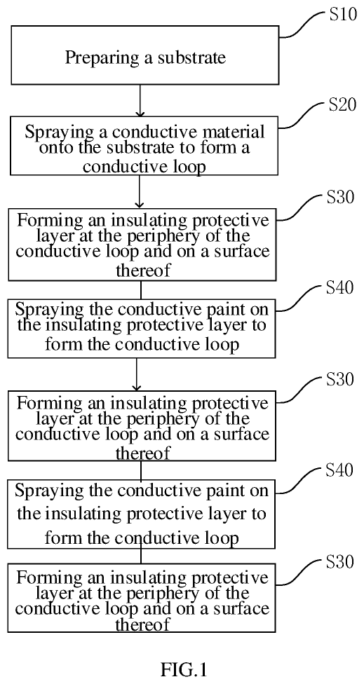

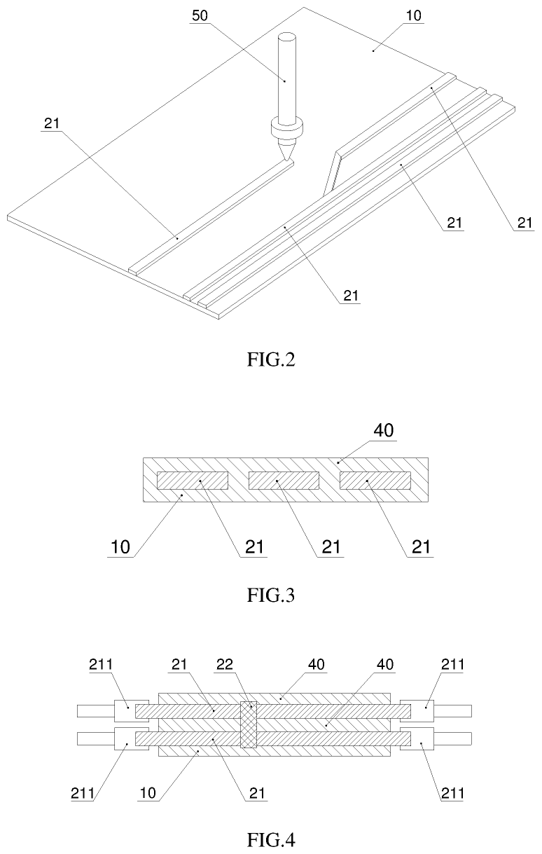

The present disclosure provides a wiring harness production method, as illustrated in FIGS. 1 and 2, including: Step S10: preparing a substrate 10; Step S20: spraying a conductive paint on the substrate 10 to form a conductive loop 21; and Step S30: forming an insulating protective layer 40 at the periphery of the conductive loop 21 and on a surface thereof.

The wiring harness production method adopts spraying to form the conductive loop 21 on the substrate 10, in which the conductive loop 21 may be connected to an external electrical component to realize an electrical connection function of the wiring harness; and performs an insulating protection by the insulating protective layer 40, thereby realizing the rapid formation of a wiring harness loop. By adopting spraying to produce the wiring harness in the wiring harness production method, the flexible production degree is high, the processing is fast and convenient, the efficiency is high, the production cost is reduced, and the method is suitable for the small-batch production of wiring harnesses.

In an embodiment, the wiring harness production method includes Step S40 performed after Step S30, in which Step S40 includes spraying the conductive paint onto the insulating protective layer 40 to form the conductive loop 21, and Step S40 and Step S30 are alternately performed one or more times in sequence. Step S20 forms one conductive layer 30 on the substrate 10; and when Step S40 is performed once, another conductive layer 30 may be formed on the formed conductive loop 21 and the insulating protective layer 40. By alternatively performing Step S40 and Step S30, a plurality of conductive layers 30 are constructed on the substrate 10 to form a multi-layer structure. Multi-layer spraying is adopted to form a plurality of conductive layers 30, so that more conductive loops 21 can be prepared under the condition of a small area of the substrate 10, thereby meeting the demand for more electrical loops.

FIGS. 3 and 4 illustrate schematic structural diagrams of a wiring harness produced by a wiring harness production method according to the present disclosure. The wiring harness illustrated in FIG. 3 has a single-layer structure, and the wiring harness illustrated in FIG. 4 has a double-layer structure. One conductive layer 30 may include a plurality of conductive loops 21. In a wiring harness with a multi-layer structure, each conductive layer 30 may have the same or different numbers and structures of the conductive loops 21.

Further, the wiring harness production method includes Step S50: punching a hole in the insulating protective layer 40 and/or the conductive loop 21, and pouring a conductive material to form a communication loop 22 that electrically connects at least two layers of the conductive loops 21. By punching the hole and pouring the conductive material, it is possible to electrically connect the conductive loops 21 of different layers, and realize the design scheme of a complex electrical loop, which is suitable for more complex wiring harnesses.

In an embodiment, the wiring harness produced by the wiring harness production method includes a plurality of conductive layers 30, and a hole is punched in the insulating protective layer 40 between two adjacent conductive layers 30 and filled with a conductive material to form the communication loop 22, which communicates the conductive loops 21 of the two adjacent conductive layers 30.

In an embodiment, the wiring harness produced by the wiring harness production method includes at least three conductive layers 30, which include an upper conductive layer 31, a middle conductive layer 32 and a lower conductive layer 33; a communication loop 22 passing through the middle conductive layer 32 is provided to be communicated with the upper conductive layer 31 and the lower conductive layer 33, respectively. In some cases, the communication loop 22 passes through and is communicated with the conductive loop 21 of the middle conductive layer 32, so that the upper conductive layer 31, the middle conductive layer 32 and the lower conductive layer 33 are simultaneously communicated. In other cases, the communication loop 22 passes through the middle conductive layer 32 via an area where the conductive loop 21 is not provided, communicates the upper conductive layer 31 with the lower conductive layer 33, and bypass the conductive loop 21 of the middle conductive layer 32 to avoid a communication therewith.

In some embodiments, one or more conductive layers 30 are provided between the two conductive layers 30 which are communicated with the communication loop 22, and a communication with the intermediate one or more conductive layers 30 should be avoided. It is possible to improve the conductive loop 21 in the intermediate one or more conductive layer 30. For example, the conductive loop 21 extends along a curve or a polyline to avoid the position where the communication loop 22 is disposed by hole punching. It is also possible to dispose the communication loop 22 to extend along a polyline or a curve to avoid the intermediate one or more conductive layers 30.

The hole punching and the pouring of the conductive material may be performed after each of the conductive layers 30 is formed, or at the same time of forming the conductive layer 30 and the insulating protective layer 40. For example, after one conductive layer 30 or one insulating protective layer 40 is formed, a hole is punched therein and poured with the conductive material to form the communication loop 22, and then the next conductive layer 30 or insulating protective layer 40 is continuously formed. In some cases, the conductive loops 21 in the intermediate conductive layers 30 are dense, and it is difficult for the communication loop 22 to bypass the conductive loops 21 in the intermediate conductive layers 30 just by improving the conductive loops 21. Therefore, the inventor makes a further improvement to the wiring harness production method and the wiring harness produced thereby.

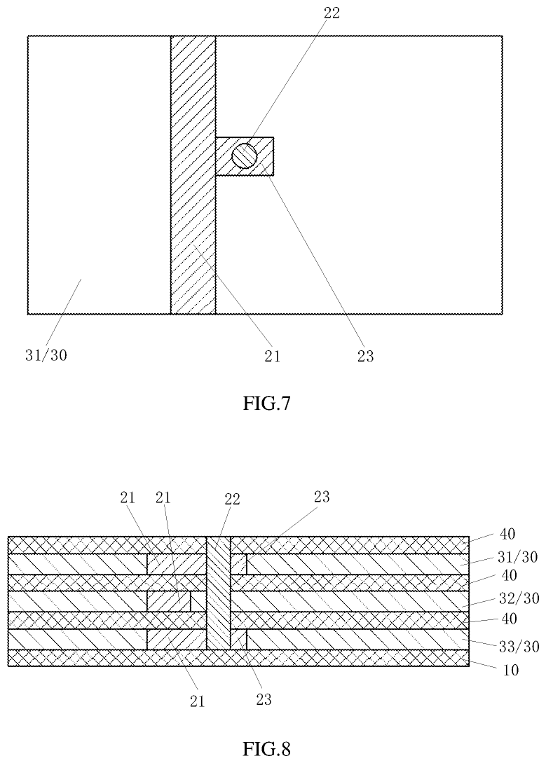

As illustrated in FIGS. 7 and 8, the wiring harness includes an upper conductive layer 31, a middle conductive layer 32 and a lower conductive layer 33; the conductive loop 21 in the upper conductive layer 31 is respectively connected to conductive protrusions 23, which are deviated from the conductive loop 21 in the middle conductive layer 32; and the communication loop 22 is respectively communicated with the conductive protrusion 23 in the upper conductive layer 31 and the conductive protrusion 23 in the lower conductive layer 33, and bypasses the conductive loop 21 in the middle conductive layer 32, thereby communicating the upper conductive layer 31 with the lower conductive layer 33 and avoiding a communication with the middle conductive layer 32.

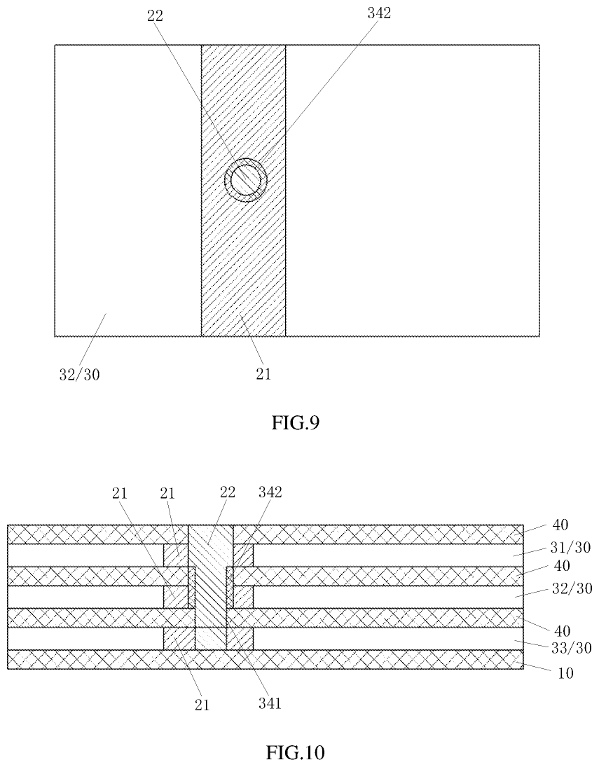

As illustrated in FIGS. 9 and 10, the wiring harness includes an upper conductive layer 31, a middle conductive layer 32 and a lower conductive layer 33; the hole punching position in Step S50 directly faces the conductive loop 21 of the upper conductive layer 31, the conductive loop 21 of the lower conductive layer 33 and the conductive loop 21 of the middle conductive layer 32; the punched hole passes through the conductive loop 21 of the middle conductive layer 32, and is provided with an insulating sleeve 34 which is located in the middle conductive layer 32 and isolates the conductive loop 21 of the middle conductive layer 32; and a conductive material is poured into the hole and the insulating sleeve 34, thereby avoiding a communication between the communication loop 22 and the middle conductive layer 32.

Further, as illustrated in FIG. 10, the hole punched in Step S50 is a stepped hole, which has a part with a small inner diameter in the lower conductive layer 33 for the convenience of disposing the insulating sleeve 34, and a stepped part of the stepped hole can support the insulating sleeve 34.

The magnitude of the conduction current of the conductive loop 21 may be adjusted by adjusting a cross-sectional area of the conductive loop 21, e.g., by adjusting the thickness or the width of the conductive loop 21. In the wiring harness production method, the cross-sectional area of the conductive loop 21 may be adjusted by adjusting spraying parameters in Step S20. An appropriate thickness or width of the conductive loop 21 may be achieved according to the required magnitude of the conduction current of the conductive loop 21. The wiring harness production method is suitable for the processing of the multi-wire diameter loop, and is convenient to control the conductivity of the conductive loop 21.

In an embodiment, Step S20 and Step S40 respectively use a nozzle 50, through which the conductive paint is sprayed out. By using the nozzle 50 with different sizes or shapes, a width and a thickness of the cross section of the conductive loop 21 can be adjusted.

Further, the nozzle 50 has a square discharge port 501, which is beneficial to making the width and the thickness of the cross section of the conductive loop 21 uniform, ensuring the stability of the cross section, and avoiding the situation that during spraying, there is more discharge at a middle position of the cross section and less discharge at two sides thereof and finally the conductive loop 21 is formed such that the middle of the cross section is high and the two sides thereof are low.

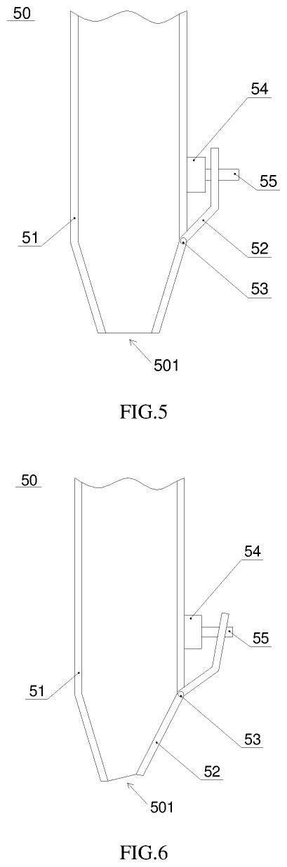

In an embodiment, the size of the discharge port 501 of the nozzle 50 is adjustable to adjust the width and the thickness of the cross section of the conductive loop 21. As illustrated in FIGS. 5 and 6, the nozzle 50 includes a nozzle body 51, and a movable sidewall 52 connected to the nozzle body 51 through a hinge 53. By rotating the movable sidewall 52 around a center of the hinge 53 relative to the nozzle body 51, a mounting angle of the movable sidewall 52 can be adjusted to adjust a position of a lower end of the movable sidewall 52, thereby adjusting the size of the discharge port 501 of the nozzle 50.

Specifically, the nozzle body 51 is connected to a motor 54, and a shaft of the motor 54 is connected to a drive screw 55; the movable sidewall 52 is provided with a threaded hole which is engaged with the drive screw 55. The motor 54 drives the drive screw 55 to rotate, and the drive screw 55 drives the movable sidewall 52 to rotate around the center of the hinge 53 to adjust the size of the discharge port 501 of the nozzle 50. The discharge port 501 of the nozzle 50 is square, which is convenient to adjust the cross-sectional area of the conductive loop 21 by adjusting the size of the discharge port 501.

The width and the thickness of the cross section of the conductive loop 21 may also be adjusted by adjusting a spraying distance of the nozzle 50, e.g., by adjusting a distance from the nozzle 50 to the substrate 10. The width and the thickness of the cross section of the conductive loop 21 may further be adjusted by adjusting a spraying speed, i.e., a moving speed of the nozzle 50. Preferably, the spraying distance is 5 mm to 100 mm and the spraying speed is 0.1 mm/s to 100 mm/s, which can prevent the spraying material from being too dispersed, and avoid the trajectory the conductive loop 21 from being fractured, thereby ensuring the conductivity.

The nozzle 50 may be mounted on a servo mechanism or a manipulator, which drives the nozzle 50 to spatially move to spray the conductive loop 21 at various angles, thereby forming a wiring harness with a spatial structure, which is convenient to process and realize a wiring harness with a complex spatial structure, and ensure stable spraying to keep a uniform size of the conductive loop 21. Further, the nozzle 50 is mounted on a three-axis servo mechanism or a six-axis manipulator.

Specifically, the three-axis servo mechanism is provided with a moving guide rail in each of directions X, Y and Z, and the movement in each direction is driven by the servo motor 54, so that a three-dimensional processing trajectory is realized under the program control, and the conductive loop 21 with a spatial trajectory is formed by spraying. The six-axis manipulator may drive the nozzle 50 to move more flexibly, thereby forming the conductive loop 21 with a more complicated spatial trajectory by spraying.

In an embodiment, one conductive layer 30 formed in Step S20 includes a plurality of conductive loops 21 to prepare more conductive loops 21. In the same conductive layer 30, the plurality of conductive loops 21 are disconnected from or electrically connected to each other. For example, the respective conductive loops 21 in the same conductive layer 30 are disconnected from each other. In the same conductive layer 30, at least two conductive loops 21 are electrically connected to each other. The conductive loops 21 in each of the conductive layers 30 are set depending on the electrical connection function to be realized.

In an embodiment, in Step S20, high-pressure airless spraying, electrostatic spraying or air spraying is adopted to spray a conductive paint mixed with an adhesive onto the substrate 10. The conductive paint is mixed with the adhesive and sprayed on a molding surface, and the paint is secured to form the conductive loop 21. Specifically, in the case of air spraying, compressed air is used to atomize the paint for spraying. In the case of high-pressure airless spraying, the paint is pressurized to a pressure of 9.8 MPa to 29.4 MPa by a pressurizing pump, and then sprayed through a small hole of the olive shaped nozzle 50. When rushing out of the nozzle 50 into the atmosphere, the high-pressure paint immediately expands violently and breaks into extremely fine mist, which is directly sprayed onto the surface of the substrate 10 or the formed insulating protective layer 40. In the high-pressure airless spraying, the paint is pressurized to a high pressure by the pressurizing pump and itself is not mixed with the compressed air. In the case of electrostatic spraying, the atomized paint is negatively charged under the action of a high-voltage DC electric field using a corona discharge principle, and is adsorbed on the surface of a positively charged base for discharging, in which an electrostatic spraying device includes a spray gun, a spray cup and an electrostatic spraying high-voltage power source. Exemplarily, the paint is also mixed with a solvent and an additive. The conductive paint may be one or more of powders of copper, aluminum, gold, silver, graphite, etc. The adhesive includes at least one from a group consisting of epoxy resin, polyester resin, acrylic resin, polyamide resin, modified phenolic resin and cellulose resin.

In an embodiment, the conductive paint includes a metallic material, and in Step S20, thermal spraying, electric arc spraying or plasma spraying is adopted to spray the molten conductive paint onto the substrate 10. Specifically, in the case of thermal spraying, the paint is heated and melted, atomized into extremely fine particles by high-speed airflow, and sprayed on the molding surface at a high speed, then the paint is secured to form a coating layer. In the case of electric arc spraying, the metallic powder is continuously fed, and the arc produced by the metallic powder is utilized to melt the metal, and the molten metal is atomized by high-speed airflow, then the atomized metal particles are accelerated and sprayed on the molding surface to form the conductive loop 21. In the case of plasma spraying, the conductive paint is heated to a molten or semi-molten state using a plasma electric arc driven by direct current as a heat source, and sprayed onto the molding surface at a high speed to form a firmly attached conductive loop 21. The thermal spraying includes flame spraying and electric arc spraying, and the difference therebetween only lies in whether the material is melted by a flame or an electric arc. The plasma spraying is one type of electric arc spraying, in which the plasma electric arc can produce a high temperature to heat the metallic powder. The conductive paint may be a metallic powder or a metal wire.

When being a metallic powder, the conductive paint includes one or combinations of nickel or alloy thereof, cadmium or alloy thereof, zirconium or alloy thereof, chromium or alloy thereof, cobalt or alloy thereof, manganese or alloy thereof, aluminum or alloy thereof, tin or alloy thereof, titanium or alloy thereof, zinc or alloy thereof, copper or alloy thereof, silver or alloy thereof, and gold or alloy thereof. When being a nonmetallic powder, the conductive paint includes one or combinations of conductive ceramic, carbon-containing conductor, solid electrolyte, mixed conductor and conductive polymer material, in which the carbon-containing conductor is one or more of graphite powder, carbon nanotube material and graphene material.

Step S40 may adopt the same process method as Step S20, which is not repeated here.

In an embodiment, the insulating protective layer 40 is made of one or combinations of polyvinyl chloride, polyurethane, nylon, polypropylene, silicone rubber, crosslinked polyolefin, synthetic rubber, polyurethane elastomer, crosslinked polyethylene and polyethylene. In Step S30, one or more processes of coating, printing, spraying, immersion plating and injection molding to form the insulating protective layer 40, so as to ensure the insulating protective effect of the insulating protective layer 40 on the conductive layer 30.

Step S10 includes cleaning the surface of the substrate 10. The cleaning mode of the substrate 10 may be one or more of solution washing and cleaning, ultrasonic cleaning and high-pressure washing to remove oil stains, impurities and dirt.

In an embodiment, the wiring harness production method further includes Step S05 performed before Step S10, in which Step S05 includes: providing an insulating layer on the surface of the substrate 10, and forming the conductive loop 21 on a surface of the insulating layer. When the substrate 10 is made of a conductive material, the insulation between the conductive loops 21 can be ensured by providing an insulating layer on the substrate 10 in advance. The insulating layer may be formed by one or more processes of coating, printing, spraying, immersion plating and injection molding. When the substrate 10 is made of an insulating material, the insulating layer may not be provided.

The substrate 10 may adopt a profile modeling structure so as to facilitate the adaptation of the produced wiring harness to the application environment. The substrate 10 may adopt a flexible substrate 10, so that the produced wiring harness can be suitable for various mounting situations and convenient to be applied to electrical components in complex mounting environments, which is beneficial to reducing the interference of vibration factors and ensuring the stability of use in environments with high vibration requirements. The substrate 10 may be a constituent part of an electrical component, and can realize the integrated production of the components and the wiring harness, thereby achieving the rapid mounting and dismounting of the wiring harness. For example, the substrate 10 is a component of a vehicle body or a vehicle-mounted electrical component, and the conductive loop 21 is integrated with the substrate 10, so that the wiring harness can be replaced by replacing the substrate 10, which not only saves the maintenance man-hours, but also reduces the maintenance cost. For example, an inner lining plate of a vehicle door may be used as the substrate 10 of a door wiring harness, and the inner lining plate can be directly replaced during maintenance. The substrate 10 may also be a component of a body in white, a bumper, a roof, an inner door panel, a seat frame or any vehicle-mounted electrical component.

Under normal circumstances, the spraying process has the characteristics of large coverage, uniform thickness and strong adhesion, and is generally used in surface coating such as anti-corrosion and wear resistance. In the wiring harness production method, the conductive loop 21 is made by the spraying process, so that the width and the thickness can be adjusted and the coverage is small.

In an embodiment, the wiring harness production method includes Step S15 and Step S60, in which Step S15 is performed before Step S20 and Step S60 is performed before Step S30; Step S15 includes spraying a lower shielding layer on the substrate, and Step S60 includes spraying an upper shielding layer onto the periphery of the insulating protective layer, in which the upper shielding layer and the lower shielding layer are electrically connected to enclose the conductive loop 21.

The upper shielding layer and the lower shielding layer are connected through a shielding layer on a sidewall of the wiring harness, so that the upper shielding layer, the lower shielding layer and the shielding layer on the sidewall of the wiring harness form a box structure to surround the conductive loop 21. A shielding structure is provided outside the wiring harness, so that a signal in the wiring harness can be shielded from electromagnetic interference at a position with strong electromagnetic interference, thereby ensuring the stability of the signal.

In a case where the wiring harness includes a plurality of conductive layers, the upper shielding layer is provided above the uppermost conductive layer, that is, Step S60 is performed before Step S30 which is performed last time. Under the condition that the surface of the substrate is provided with an insulating layer, the lower shielding layer is provided above the insulating layer. The shielding layer on the sidewall of the wiring harness may be formed by spraying or printing, or formed of an aluminum foil.

In an embodiment, the wiring harness production method further includes Step S70 performed after Step S30, in which Step S70 includes crimping or welding connecting terminals at a tail end of the conductive loop 21, and by mutual plugging between the connecting terminals, achieving electrical connection between different wiring harnesses or between a wiring harness and an electrical component.

As illustrated in FIG. 4, the tail end of the conductive loop 21 is provided with a connecting terminal 211, which may be a connecting finger, a pin terminal or a welding electrical wire, so as to be connected to any other electrical loop.

Further, the wiring harness production method further includes Step S80 performed after Step S70, in which Step S80 includes providing sheaths at the tail end of the conductive loop 21, and accommodate the connecting terminals in the sheaths, so as to achieve the contact connection between the connecting terminals in the sheaths through butting between the sheaths. In some cases, a plurality of connecting terminals 211 are provided in one sheath, and two matched sheaths are connected to ensure the firmness of connection, so that the electrical connection between the connecting terminals 211 is more reliable and stable.

In an embodiment, the wiring harness production method further includes Step S90 performed after Step S30, in which Step S90 includes providing heat sinks on the insulating protective layer, and quickly dissipating the heat generated by the current of the wiring harness into the air through the heat sinks, which is beneficial to decreasing the temperature of the wiring harness and reducing the fusing risk of the conductive loop 21.

### Embodiment 2

The present disclosure provides a nozzle 50, which is applied to the wiring harness production method, and a conductive paint is sprayed out through the nozzle 50. A width and a thickness of a cross section of the conductive loop 21 may be adjusted by adjusting a size or a shape of a discharge port 501 of the nozzle 50. As illustrated in FIGS. 5 and 6, the discharge port 501 of the nozzle 50 is square, which is beneficial to making the width and the thickness of the cross section of the conductive loop 21 uniform, ensuring the stability of the cross section, and avoiding the situation that during spraying, there is more discharge at a middle position of the cross section and less discharge at two sides thereof, and finally the conductive loop 21 is formed such that the middle of the cross section is high and the two sides thereof are low.

In an embodiment, the size of the discharge port 501 of the nozzle 50 is adjustable to adjust the width and the thickness of the cross section of the conductive loop 21. As illustrated in FIGS. 5 and 6, the nozzle 50 includes a nozzle body 51, and a movable sidewall 52 connected to the nozzle body 51 through a hinge 53. By rotating the movable sidewall 52 around a center of the hinge 53 relative to the nozzle body 51, a mounting angle of the movable sidewall 52 can be adjusted to adjust a position of a lower end of the movable sidewall 52, thereby adjusting the size of the discharge port 501 of the nozzle 50.

Specifically, the nozzle body 51 is connected to a motor 54, and a shaft of the motor 54 is connected to a drive screw 55; the movable sidewall 52 is provided with a threaded hole which is engaged with the drive screw 55. The motor 54 drives the drive screw 55 to rotate, and the drive screw 55 drives the movable sidewall 52 to rotate around the center of the hinge 53 to adjust the size of the discharge port 501 of the nozzle 50. The discharge port 501 of the nozzle 50 is square, which is convenient to adjust the cross-sectional area of the conductive loop 21 by adjusting the size of the discharge port 501.

### Embodiment 3

The present disclosure provides a wiring harness, which is produced by the wiring harness production method, the wiring harness including: a substrate 10, at least one conductive loop 21 and at least one insulating protective layer 40, in which each conductive loop 21 is located between the substrate 10 and the outermost insulating protective layer 40, and the conductive loop 21 and the insulating protective layer 40 are alternately distributed. The wiring harness is suitable for flexible production and small-batch production, the processing is fast and convenient, the efficiency is high, and the production cost is reduced.

In an embodiment, the conductive loop has a cross-sectional width of 0.1 mm to 68 mm. In the wiring harness, the cross-sectional area of the conductor determines the current that the conductor can conduct. In general, the conductor that realizes signal conduction has small current, so the cross-sectional area thereof is small. For example, a minimum cross-sectional area of a signal line in a vehicle wiring harness may be 0.1 mm2. But the conductor that realizes power conduction has large current, so the cross-sectional area thereof is large. For example, a maximum cross-sectional area of the wiring harness for a vehicle battery reaches 260 mm2.

When the width of the conductive loop 21 is less than 0.1 mm, in order to obtain a conductor with a cross-sectional area of 0.1 mm2, it is necessary to spray the conductive loop 21 with a thickness of at least 1 mm. Since the thickness increases as the width decreases, in order to obtain a large thickness, it is necessary to perform spraying for multiple times, which wastes the man-hours and reduces the processing efficiency. In addition, the conductive loop 21 is too narrow, the strength cannot meet the requirement, and the layout of the wiring harness is restricted, so that the height of the wiring harness cannot be reduced.

When the width of the conductive loop 21 is greater than 68 mm, in order to obtain a conductor with a cross-sectional area of 260 mm2, it is necessary to spray a conductor with a thickness of at least 3.82 mm. As the width decreases, the thickness increases, but the area of the sprayed conductive loop 21 also increases and the occupied area of the wiring harness cannot be reduced.

Therefore, the inventor chooses the cross-sectional width of the conductive loop to be 0.1 mm to 68 mm, and the conductors with different cross-sectional areas can be obtained by spraying the conductive loops 21 with different thicknesses.

Through multiple experiments, the inventor acquires that when the cross-sectional width of the conductive loop is 0.5 mm to 58 mm, an aspect ratio of the sprayed conductive loop 21 is within a reasonable range, and the thickness range is suitable for spraying and processing, while the occupied area will not be wasted. Therefore, the inventor preferably chooses the cross-sectional width of the conductive loop to be 0.5 mm to 58 mm.

In an embodiment, the conductive paint includes conductive filler, adhesive, solvent and additive, and the conductive filler includes one or combinations of metallic powder, conductive ceramic, carbon-containing conductor, solid electrolyte, mixed conductor and conductive polymer material.

In an embodiment, the carbon-containing conductor is one or combinations of graphite powder, carbon nanotube material and graphene material.

In an embodiment, the metallic powder may be one or more of nickel or alloy thereof, cadmium or alloy thereof, zirconium or alloy thereof, chromium or alloy thereof, cobalt or alloy thereof, manganese or alloy thereof, aluminum or alloy thereof, tin or alloy thereof, titanium or alloy thereof, zinc or alloy thereof, copper or alloy thereof, silver or alloy thereof, and gold or alloy thereof. Exemplarily, the most commonly used metal material for the conductor is copper or copper alloy, because the conductivity of copper is good among metals, and copper is not a precious metal while being convenient for processing and good in ductility. However, with the increasing price of copper, the material cost of the conductor made of copper is higher and higher. To this end, people begin to look for alternatives to copper to reduce the cost. The content of metallic aluminum in the earth's crust is about 7.73%, and after the optimization of the refining technology, the price thereof is relatively low. In addition, compared with copper, aluminum is lighter, and its conductivity is second only to copper, so that aluminum or aluminum alloy can partially replace copper or copper alloy in the field of electrical connections.

In an embodiment, the insulating protective layer is made of one or combinations of polyvinyl chloride, polyurethane, nylon, polypropylene, silicone rubber, crosslinked polyolefin, synthetic rubber, polyurethane elastomer, crosslinked polyethylene and polyethylene.

In an embodiment, the insulating protective layer has a breakdown strength of 0.3 KV/mm to 35 KV/mm. The breakdown strength is also called a dielectric breakdown strength, which refers to a highest electric field strength that a material can withstand without being damaged (broken down) in an electric field. When the breakdown strength of the insulating protective layer is lower than 0.3 KV/mm, a thin part of the insulating protective layer may be broken down under a normal voltage, resulting in invalid insulation. When the breakdown strength of the insulating protective layer is higher than 35 KV/mm, the choice of a material with too high breakdown strength will increase the cost of an integrated wiring harness assembly and cause design waste, because a high voltage greater than 35 KV will not occur in the general vehicle-mounted environment.

In an embodiment, the insulating protective layer has a thickness of 0.03 mm to 5 mm. If the thickness of the insulating protective layer is less than 0.03 mm, not only the breakdown voltage of the insulating protective layer cannot be ensured to be higher than the working voltage, but also the wear resistance of the insulating protective layer cannot be guaranteed. After repeated scraping and grinding, the insulating protective layer may be damaged to expose the conductor, which leads to a current leakage or a short circuit, resulting in a line damage and a functional failure. When the thickness of the insulating protective layer is 5 mm, the breakdown voltage, the insulation resistance and the wear resistance of the insulating protective layer can meet the requirements. However, if the thickness is greater than 5 mm, there may be defects such as air holes and collapse during processing due to the large thickness of the insulating protective layer, which degrades the performance and wastes the material of the insulating protective layer, and increases the processing procedures and time. Therefore, the inventor chooses the thickness of the insulating protective layer as 0.03 mm to 5 mm.

The substrate 10 may adopt a profile modeling structure, so as to facilitate the adaptation of the produced wiring harness to the application environment. The substrate 10 may adopt a flexible substrate 10, so that the produced wiring harness can be suitable for various mounting situations and convenient to be applied to electrical components in complex mounting environments, which is beneficial to reducing the interference of vibration factors and ensuring the stability of use in environments with high vibration requirements. The substrate 10 may be a constituent part of an electrical component, and can realize the integrated production of the components and the wiring harness, thereby achieving the rapid mounting and dismounting of the wiring harness. For example, the substrate 10 is a component of a vehicle body or a vehicle-mounted electrical component, and the conductive loop 21 is integrated with the substrate 10, so that the wiring harness can be replaced by replacing the substrate 10, which not only saves the maintenance man-hours, but also reduces the maintenance cost. For example, an inner lining plate of a vehicle door may be used as the substrate 10 of a door wiring harness, and the inner lining plate can be directly replaced during maintenance. The substrate 10 may also be a component of a body in white, a bumper, a roof, an inner door panel, a seat frame or any vehicle-mounted component.

Generally, the printed circuit board mainly serves as a circuit board to mount electrical components and realize specific electrical functions. The wiring harness is different from the conventional printed circuit board in that the wiring harness serves to conduct current and transmit signals. The tail end of the conductive loop 21 is provided with a connecting terminal 211, which may be a connecting finger, a pin terminal, a welding electrical wire or the like so as to connect the conductive loop 21 with a power source or an electrical component.

At present, the vehicle wiring harness is generally produced separately by a wiring harness factory, where electrical wires, terminals, sheaths, positioning pieces, seals, brackets, etc. are processed and assemble together to form a complete wiring harness, and then delivered to a vehicle factory, where the wiring harness is assembled to the vehicle body depending on the working station during final assembly, so the mounting is difficult and labor is wasted.

The wiring harness may be directly mounted on a sheet metal of the vehicle body, an instrument panel or an electrical component without being disposed separately, and the mounting of the wiring harness can be completed once the mounting of vehicle components is completed, thereby saving the man-hours of the final assembly of the vehicle and reducing the manual operations by at least 60%.

Those described above are merely illustrative specific embodiments of the present disclosure, rather than limitations to the scope of the present disclosure. Any equivalent change or modification made by those skilled in the art without departing from the concept and principle of the present disclosure should fall within the protection scope of the present disclosure.

1. A wiring harness production method, comprising:
Step S10: preparing a substrate;
Step S20: spraying a conductive material onto the substrate to form a conductive loop; and
Step S30: forming an insulating protective layer at the periphery of the conductive loop and on a surface thereof.

2. The wiring harness production method according to claim 1, further comprising Step S40 performed after Step S30, wherein Step S40 comprises spraying the conductive material onto the insulating protective layer to form the conductive loop; and
Step S40 and Step S30 are alternately performed one or more times in sequence.

3. The wiring harness production method according to claim 2, further comprising:
Step S50: punching a hole in the insulating protective layer and/or the conductive loop, and pouring a conductive material to form a communication loop that electrically connects at least two layers of the conductive loops.

4. The wiring harness production method according to claim 1, further comprising:
Step S15: spraying a lower shielding layer onto the substrate; and
Step S60: spraying an upper shielding layer onto the periphery of the insulating protective layer, wherein the upper shielding layer and the lower shielding layer are electrically connected to enclose the conductive loop;
Step S15 is performed before Step S20, and Step S60 is performed before Step S30.

5. The wiring harness production method according to claim 1, wherein in Step S20, a nozzle which has a square discharge port is adopted.

6. The wiring harness production method according to claim 5, wherein the nozzle is mounted on a three-axis servo mechanism or a six-axis manipulator.

7. The wiring harness production method according to claim 1, wherein in Step S2 high-pressure airless spraying, electrostatic spraying or air spraying is adopted to spray a conductive paint mixed with an adhesive onto the substrate.

8. The wiring harness production method according to claim 1, wherein the conductive paint comprises a metallic material, and in Step S20, thermal spraying, electric arc spraying or plasma spraying is adopted to spray the molten conductive paint onto the substrate.

9. The wiring harness production method according to claim 1, wherein one conductive layer formed in Step S20 comprises a plurality of the conductive loops which are disconnected from or electrically connected to each other in the same conductive layer.

10. The wiring harness production method according to claim 1, further comprising Step S05 performed before Step S10, wherein Step S05 comprises providing an insulating layer on a surface of the substrate, and forming the conductive loop on a surface of the insulating layer.

11. The wiring harness production method according to claim 1, further comprising Step S70 performed after Step S30, wherein Step S70 comprises: crimping or welding connecting terminals at a tail end of the conductive loop.

12. The wiring harness production method according to claim 11, further comprising Step S80 performed after Step S70, wherein Step S80 comprises providing sheaths at the tail end of the conductive loop, and accommodate the connecting terminals in the sheaths.

13. The wiring harness production method according to claim 1, further comprising Step S90 performed after Step S30, wherein Step S90 comprises providing heat sinks on the insulating protective layer.

14. The wiring harness production method according to claim 1, wherein Step S30 adopts one or more processes of coating, printing, spraying, immersion plating and injection molding to form the insulating protective layer.

15. A nozzle, which is applied to the wiring harness production method according to claim 1, and a discharge port of the nozzle is square.

16. A wiring harness, which is produced by the wiring harness production method according to claim 1, the wiring harness comprising: a substrate, at least one conductive loop and at least one insulating protective layer, wherein each conductive loop is located between the substrate and the outermost insulating protective layer, and the conductive loop and the insulating protective layer are alternately distributed.

17. The wiring harness according to claim 16, wherein the conductive loop has a cross-sectional width of 0.1 mm to 68 mm.

18. (canceled)

19. The wiring harness according to claim 16, wherein the conductive paint comprises conductive filler, adhesive, solvent and additive, and the conductive filler comprises one or combinations of metallic powder, conductive ceramic, carbon-containing conductor, solid electrolyte, mixed conductor and conductive polymer material; and
the carbon-containing conductor is one or combinations of graphite powder, carbon nanotube material and graphene material.

20. (canceled)

21. (canceled)

22. The wiring harness according to claim 16, wherein the insulating protective layer is made of one or combinations of polyvinyl chloride, polyurethane, nylon, polypropylene, silicone rubber, crosslinked polyolefin, synthetic rubber, polyurethane elastomer, crosslinked polyethylene and polyethylene.

23. The wiring harness according to claim 16, wherein the insulating protective layer has a breakdown strength of 0.3 KV/mm to 35 KV/mm.

24. (canceled)
